(19) United States
(12) Patent Application Publication
(10) Pub. No.: US 2008/0047745 A1
(43) Pub. Date: Feb. 28, 2008

(54) Flexible clip-on shielding and/or grounding strips

(76) Inventors: David Christopher Smeltz, Easton, PA (US); Edward W. Stevens, Stroudsburg, PA (US)

Correspondence Address: HARNESS, DICKEY, & PIERCE, P.L.C, 7700 BONHOMME, STE 400, ST. LOUIS, MO, 63105, US

(21) Appl. No.: 11/640,802

(22) Filed: Dec. 18, 2006

Related U.S. Application Data
(60) Provisional application No. 60/840,999, filed on Aug. 30, 2006.
(60) Provisional application No. 60/840,532, filed on Aug. 28, 2006.

(51) Int. Cl. H05K 9/00

(52) U.S. Cl. 174/355

(57) ABSTRACT

According to various aspects, exemplary embodiments are provided of flexible clip-on shielding and/or grounding strips capable of being clipped onto and disposed along a curved edge portion of a mounting surface. In one exemplary embodiment, a flexible clip-on shielding includes an array of generally transversely extending slots. At least some of the slots have a closed end portion and an open end portion such that the closed end portions are at alternating ends of the slots and such that the open end portions are at alternating ends of the slots. Finger elements are defined by the slots. At least one finger element is defined generally between a first pair of slots with at least one slot between the first pair of slots. At least one other finger element is defined generally between a second pair of slots without another slot between the second pair of slots.

### CROSS-REFERENCE TO RELATED APPLICATION

This application claims the benefit of U.S. Provisional Application No. 60/840,999 filed Aug. 30, 2006 and U.S. Provisional Application No. 60/840,532 filed Aug. 28, 2006. The disclosures of the above applications are incorporated herein by reference.

### FIELD

The present disclosure generally relates to electromagnetic interference (EMI)/radio frequency interference (RFI) shielding and/or grounding strips.

### BACKGROUND

The statements in this section merely provide background information related to the present disclosure and may not constitute prior art.

Selected electronic parts radiate electromagnetic waves, which can cause noise or unwanted signals to appear in electronic devices existing within a certain proximity of the radiating parts. Accordingly, it is not uncommon to provide shielding and/or grounding for electronic components that use circuitry that emits or is susceptible to electromagnetic radiation. These components may be shielded to reduce undesirable electromagnetic interference and/or susceptibility effects with the use of a conductive shield that reflects or dissipates electromagnetic charges and fields. Such shielding may be grounded to allow the offending electrical charges and fields to be dissipated without disrupting the operation of the electronic components enclosed within the shield.

As used herein, the term “EMI” should be considered to generally include and refer to EMI emissions and RFI emissions, and the term “electromagnetic” should be considered to generally include and refer to electromagnetic and radio frequency from external sources and internal sources. Accordingly, the term shielding (as used herein) generally includes and refers to EMI shielding and RFI shielding, for example, to prevent (or at least reduce) ingress and egress of EMI and RFI relative to a housing or other enclosure in which electronic equipment is disposed.

### SUMMARY

According to various aspects, exemplary embodiments are provided of flexible clip-on shielding strips. In one exemplary embodiment, a flexible clip-on shielding strip includes a generally longitudinally extending region, and an array of generally transversely extending slots along the generally longitudinally extending region. Each slot has a closed end portion and an open end portion such that the closed end portions are at alternating ends of the slots and such that the open end portions are at alternating ends of the slots. Finger elements are defined by the slots such that, except for every fourth finger element, each finger element is defined generally between a corresponding pair of slots with another slot extending generally along the finger element between the corresponding pair of slots. Instead of another slot extending generally along the fourth finger element between the corresponding pair of slots defining the fourth finger element, every fourth finger element has a D-shaped lance feature. The D-shaped lance feature is configured for helping the shielding strip remain clipped onto a mounting surface when the D-shaped lance feature is engagingly received within an opening defined by the mounting surface.

Another exemplary embodiment includes a flexible clip-on shielding strip configured to be clipped onto and disposed along a curved edge portion of a mounting surface. In this particular embodiment, the shielding strip generally includes an array of generally transversely extending slots. At least some of the slots have a closed end portion and an open end portion such that the closed end portions are at alternating ends of the slots and such that the open end portions are at alternating ends of the slots. Finger elements are defined by the slots. At least one finger element is defined generally between a first pair of slots with at least one slot between the first pair of slots. At least one other finger element is defined generally between a second pair of slots without another slot between the second pair of slots.

Other aspects relate to methods of using flexible clip-on shielding strips. In one exemplary embodiment, the shielding strip includes finger elements defined by the slots such that at least one finger element is defined generally between a first pair of slots with at least one slot between the first pair of slots, and such that at least one other finger element is defined generally between a second pair of slots without another slot between the second pair of slots. In this exemplary embodiment, a method includes clipping the shielding strip onto a curved edge portion of a mounting surface such that the shielding strip serpentines about the curved edge portion.

Further aspects and features of the present disclosure will become apparent from the detailed description provided hereinafter. In addition, any one or more aspects of the present disclosure may be implemented individually or in any combination with any one or more of the other aspects of the present disclosure. It should be understood that the detailed description and specific examples, while indicating exemplary embodiments of the present disclosure, are intended for purposes of illustration only and are not intended to limit the scope of the present disclosure.

### DRAWINGS

The drawings described herein are for illustration purposes only and are not intended to limit the scope of the present disclosure in any way.

FIG. 1 is a perspective view of a flexible clip-on shielding and/or grounding strip according to exemplary embodiments;

FIG. 2 is another perspective view of the flexible clip-on shielding and/or grounding strip shown in FIG. 1;

FIG. 3 is another perspective view of the flexible clip-on shielding and/or grounding strip shown in FIG. 1;

FIG. 4 is an end elevation view of the flexible clip-on shielding and/or grounding strip shown in FIG. 1;

FIG. 5 is a side elevation view of the flexible clip-on shielding and/or grounding strip shown in FIG. 1;

FIG. 6 is a plan view of a blank prior to forming the blank into the flexible clip-on shielding and/or grounding strip shown in FIG. 1 according to exemplary embodiments;

FIG. 7 is an end elevation view of the flexible clip-on shielding and/or grounding strip shown in FIG. 1 with exemplary dimensions provided for purposes of illustration only according to exemplary embodiments;

FIG. 8 is a side elevation view of the flexible clip-on shielding and/or grounding strip shown in FIG. 1 with exemplary dimensions provided for purposes of illustration only according to exemplary embodiments;

FIG. 9 is a plan view of a blank prior to forming the blank into the flexible clip-on shielding and/or grounding strip shown in FIGS. 5 and 6 and providing exemplary dimensions for purposes of illustration only according to exemplary embodiments;

FIG. 10 is a partial elevation view illustrating the flexible clip-on shielding and/or grounding strip shown in FIG. 1 clipped onto the edge of a part or component according to exemplary embodiments; and

FIG. 11 is a perspective view illustrating the flexible clip-on shielding and/or grounding strip shown in FIG. 1 positioned in a serpentine-like fashion generally about an edge of a part according to exemplary embodiments.

### DETAILED DESCRIPTION

The following description is merely exemplary in nature and is in no way intended to limit the present disclosure, application, or uses. It should be understood that throughout the drawings, corresponding reference numerals indicate like or corresponding parts and features.

According to various aspects, exemplary embodiments are provided of flexible clip-on shielding strips. In one exemplary embodiment, a flexible clip-on shielding strip includes a generally longitudinally extending region, and an array of generally transversely extending slots along the generally longitudinally extending region. Each slot has a closed end portion and an open end portion such that the closed end portions are at alternating ends of the slots and such that the open end portions are at alternating ends of the slots. Finger elements are defined by the slots such that, except for every fourth finger element, each finger element is defined generally between a corresponding pair of slots with another slot extending generally along the finger element between the corresponding pair of slots. Instead of another slot extending generally along the fourth finger element between the corresponding pair of slots defining the fourth finger element, every fourth finger element has a D-shaped lance feature. The D-shaped lance feature is configured for helping the shielding strip remain clipped onto a mounting surface when the D-shaped lance feature is engagingly received within an opening defined by the mounting surface.

According to various aspects, exemplary embodiments are provided of flexible clip-on shielding strips. In one exemplary embodiment, a flexible clip-on shielding strip includes a generally longitudinally extending region, and an array of generally transversely extending slots along the generally longitudinally extending region. Each slot has a closed end portion and an open end portion such that the closed end portions are at alternating ends of the slots and such that the open end portions are at alternating ends of the slots. Finger elements are defined by the slots such that, except for every fourth finger element, each finger element is defined generally between a corresponding pair of slots with another slot extending generally along the finger element between the corresponding pair of slots. Instead of another slot extending generally along the fourth finger element between the corresponding pair of slots defining the fourth finger element, every fourth finger element has a D-shaped lance feature. The D-shaped lance feature is configured for helping the shielding strip remain clipped onto a mounting surface when the D-shaped lance feature is engagingly received within an opening defined by the mounting surface.

Another exemplary embodiment includes a flexible clip-on shielding strip configured to be clipped onto and disposed along a curved edge portion of a mounting surface. In this particular embodiment, the shielding strip generally includes an array of generally transversely extending slots. At least some of the slots have a closed end portion and an open end portion such that the closed end portions are at alternating ends of the slots and such that the open end portions are at alternating ends of the slots. Finger elements are defined by the slots. At least one finger element is defined generally between a first pair of slots with at least one slot between the first pair of slots. At least one other finger element is defined generally between a second pair of slots without another slot between the second pair of slots.

Other aspects relate to methods of using flexible clip-on shielding strips. In one exemplary embodiment, the shielding strip includes finger elements defined by the slots such that at least one finger element is defined generally between a first pair of slots with at least one slot between the first pair of slots, and such that at least one other finger element is defined generally between a second pair of slots without another slot between the second pair of slots. In this exemplary embodiment, a method includes clipping the shielding strip onto a curved edge portion of a mounting surface such that the shielding strip serpentines about the curved edge portion.

Additional aspects relate to making shielding strips. In one exemplary embodiment, a method generally includes forming an array of generally transversely extending alternating slots that define finger elements such that at least one finger element is defined generally between a first pair of slots with at least one slot therebetween, and such that at least one other finger element is defined generally between a second pair of slots without another slot therebetween. In some embodiments, a method may also generally include forming the array of slots such that every fourth finger element is defined generally between a second pair of slots without another slot therebetween. The method may further include providing the shielding strip (e.g., a finger element, etc.) with at least one protruding portion (e.g., lance, D-shaped lance, protrusion, ribs, etc.) configured to be engagingly received within at least one opening defined by a mounting surface to thereby help the shielding strip remain clipped onto the curved mounting surface. In some embodiments, each slot is formed to include an open end portion and a closed end portion such that the closed end portions are at alternating ends of the slots and such that the open end portions are at alternating ends of the slots. In some embodiments, a method may also include imparting a curvature to the shielding strip to thereby form a rounded contact portion.

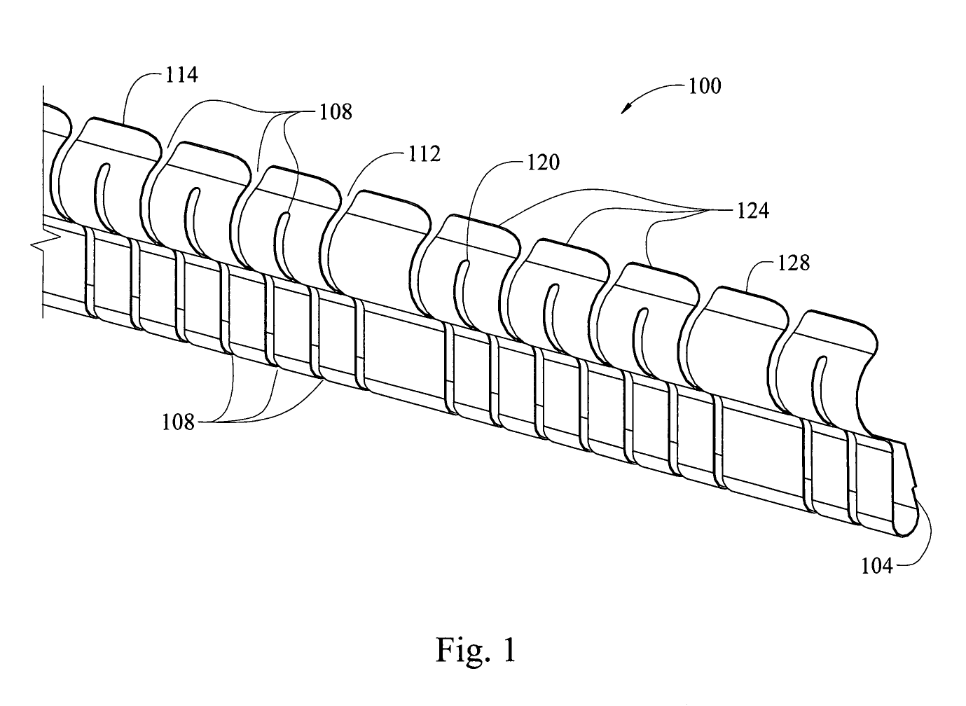

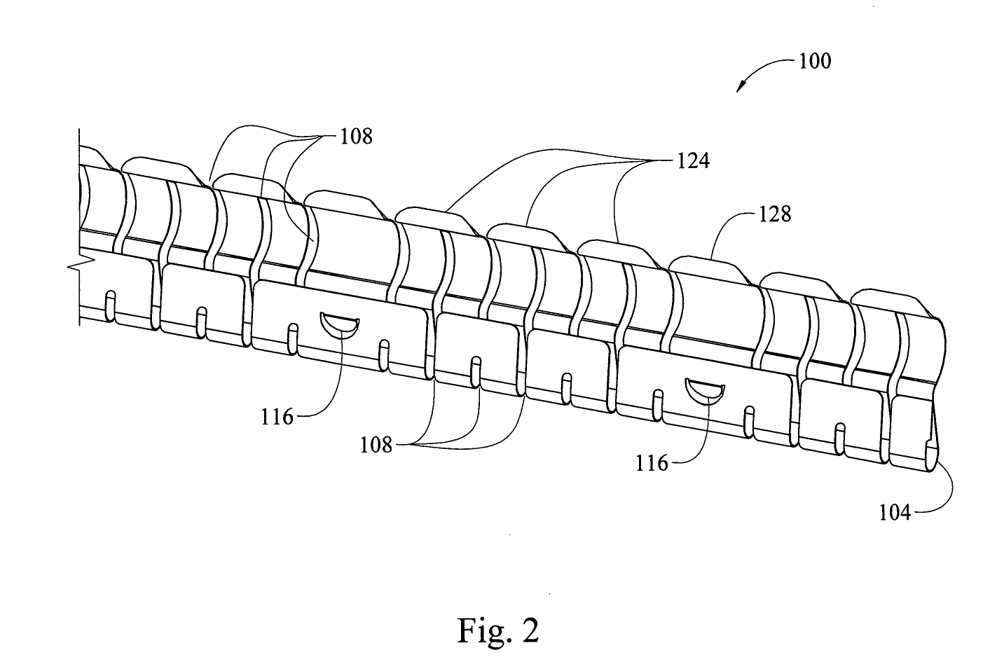

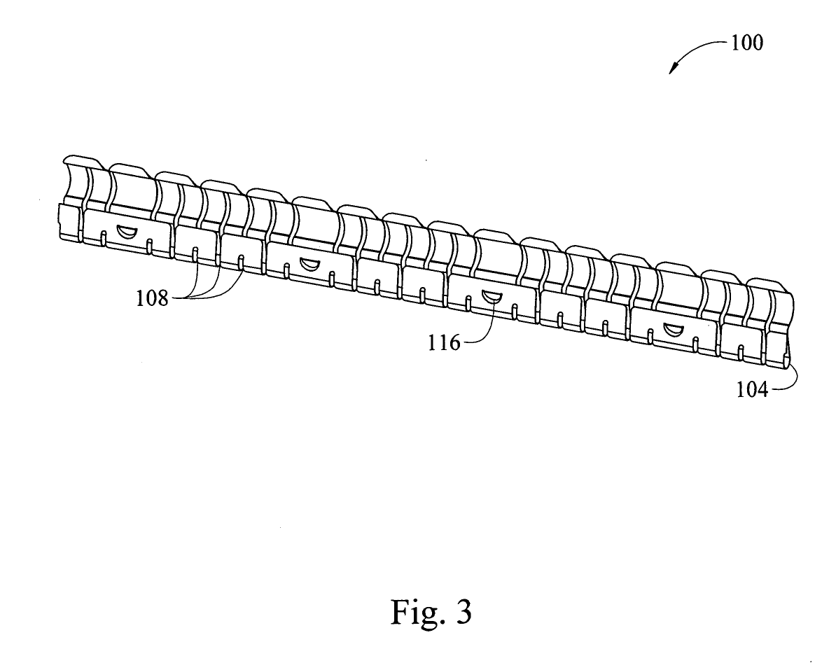

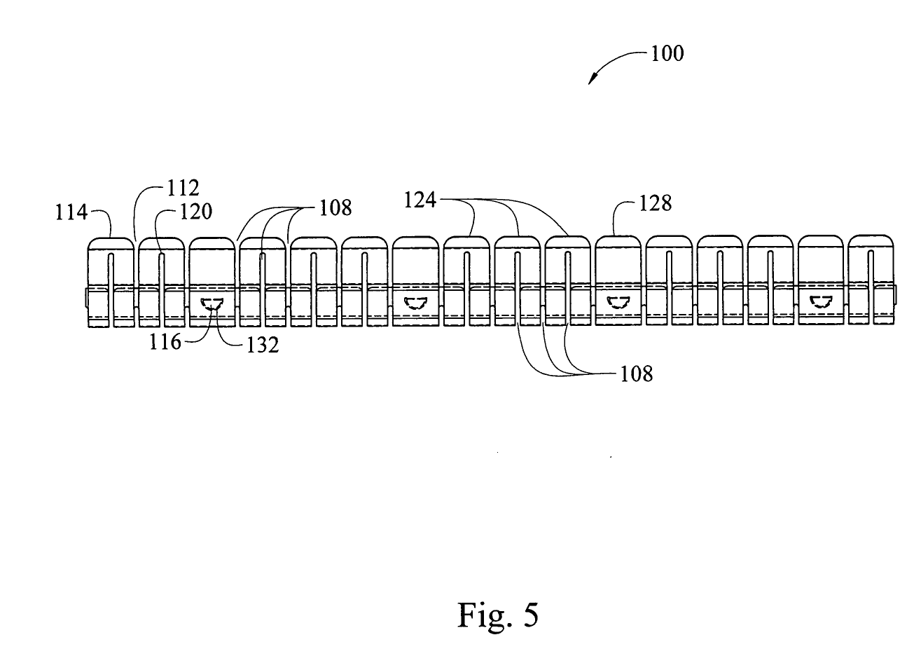

FIGS. 1 through 5 illustrate an exemplary shielding and/or grounding strip 100 embodying aspects of the present disclosure. Hereinafter, shielding and/or grounding strip 100 will be referred to as shielding strip 100 even though shielding strip 100 may also or alternatively be used as a grounding strip.

As shown in FIGS. 1 through 5, the shielding strip 100 includes a generally longitudinally extending region 104 and an array of generally transversely extending slots or slits 108. Each slot 108 includes one terminus or end portion 112 that is open or extends completely through a lateral edge 114 of the shielding strip 100. Each slot's other end portion or terminus 120 is closed, such that it does not extend completely through the lateral edge 114 of the shielding strip 100. Accordingly, the open end portions 112 are located at alternating ends of the slots 108.

The slots 108 define finger elements 124 therebetween. The slots 108 allow the finger elements 124 to flex relatively independently from one another. In one particular embodiment, the alternating slots 108 have an advance of about 0.250 inch advance and a pitch of about 0.125 inch. These dimensions (as are all dimensions set forth herein) are for purposes of illustration only as the specific dimensions for a particular application can depend, for example, upon the length of the shielding strip, desired shielding effectiveness, material properties of the shielding strip, and particular installation (e.g., thickness of the mounting surface, rail, edge, etc. on which the shielding strip will be positioned, amount of curvature or bending needed for installing the shielding strip, etc.). In addition, the dimensions may vary as a function of location such that the shielding strip is thicker in one region than another to accommodate gaps of different thickness in the enclosure and connector locations. Accordingly, the dimensions of the shielding strip may be varied accordingly in order to achieve the desired contact.

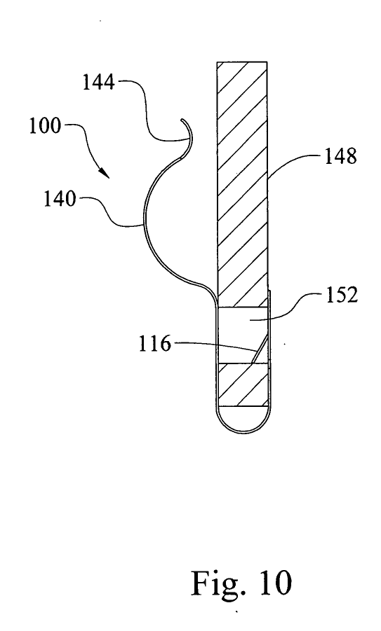

With continued reference to FIGS. 1 through 5, every fourth finger 128 is defined by a corresponding pair of slots 108 without another slot 108 therebetween. In the place of the intermediate or medial slot, each fourth finger 128 is instead provided with an opening or slit 132, which, in turn, forms a generally D-shaped lance feature 116. In use, the D-shaped lance features 116 can help retain or hold the shielding strip 100 in place, for example, after the shielding strip 100 has been installed about a radiused corner, wavy edge, curved or rounded edge, etc. For example, the D-shaped lance features 116 may help the shielding strip 100 remain clipped onto a rail, edge, or other mounting surface. In some exemplary installations, the D-shaped lance features 116 may be snapped into or engagingly received within drilled or punched holes 152 of a part (e.g., FIG. 10) or other mounting surface to create a very strong grip with excellent electrical conductivity.

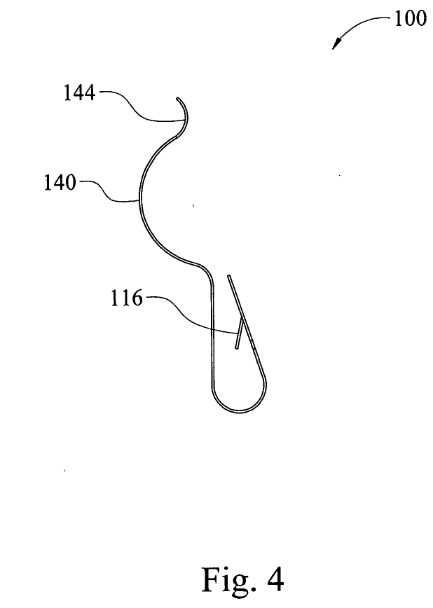

FIG. 4 illustrates the exemplary profile for the shielding strip 100. As shown, the shielding strip 100 includes a contact portion 140 defined by the finger elements 124. The finger elements 124 then curve generally downwardly from the contact portion 140 to define a ski-like bend 144. As shown in FIG. 10, the shielding strip 100 may be clipped onto the edge 148 of a part, for example, such that the contact portion 140 is spaced apart from the edge 148.

Alternative embodiments may, for example, include less or more slots and fingers than what is shown in the figures. Further embodiments may include other slot arrangements and orientations besides transversely extending slots as shown in the figures. Still further embodiments may include other means besides the D-shaped lance features 116 to facilitate holding the shielding strip in place after it has been installed. For example, other embodiments can include T-shaped lances, ribs, protrusions, etc.

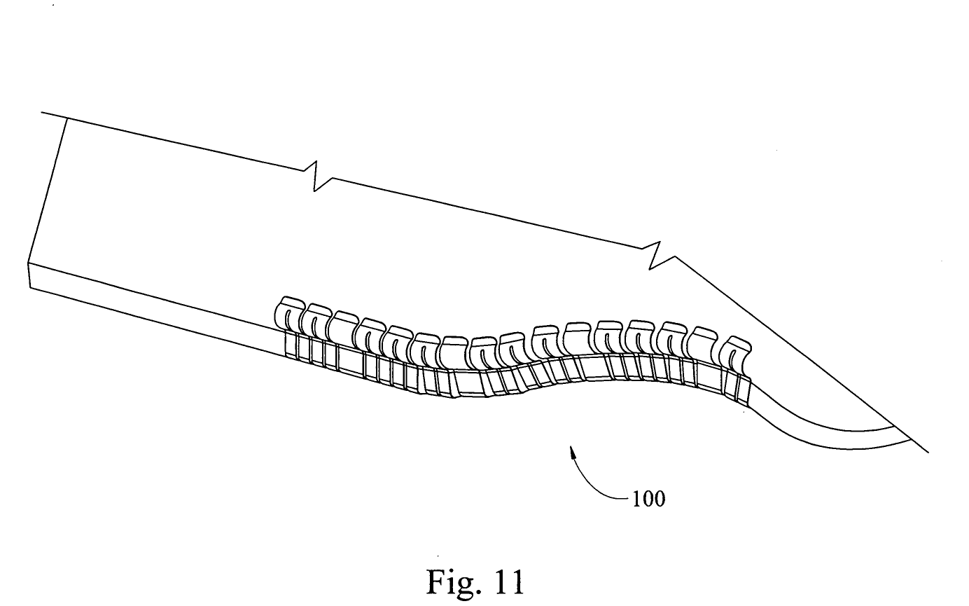

The particular alternating slot arrangement with every fourth finger missing a slot provides the shielding strip 100 with good flexibility in all three X-Y-Z directions. The alternative slot arrangement may thus allow the shielding strip 100 to be clipped onto an edge or rail in a serpentine-like manner. As shown in FIG. 11, the shielding strip 100 has sufficient flexibility to be positioned generally along or around a curved or winding edge or corner of a part or component. This flexibility may facilitate installation of the shielding strip 100, for example, where shielding is needed around a flexible edge, rounded edge, radiused corner, etc., such as a flexible printed circuit board, etc. Depending on the particular installation, the shielding strip 100 may be positioned relative to a flexible or rounded edge such that the shielding strip's contact portion 140 is on the top, bottom, side, etc. of the flexible mounting surface or rounded edge. As another exemplary installation, the flexibility of the shielding strip 100 may also prove advantageous when the shielding strip 100 is installed in an application or product where the shielding strip 100 may experience G-shock or vibrations, such as along a mounting rail of a sliding drawer. Alternative examples of possible installations for the shielding strip 100 includes front panel handles, plug-in-units, subtrack assemblies, chassis covers, backplanes, etc. The shielding strip 100 may also find use in applications where high temperature or other design considerations preclude the use of adhesive-mounted gasketing. In some embodiments, the shielding strip 100 is configured to provide shielding effectiveness of greater than one hundred decibels for one hundred megahertz plane wave.

The shielding strip 100 may be used as a shielding and/or grounding strip by contacting another surface that would bear against the contact portion 140 defined by the finger elements 124, for example, with a force having a component perpendicular to a longitudinal axis of the shielding strip 100. In use, the finger elements 124 and contact portion 140 can be borne against by another surface causing the finger elements 124 to flex along their length, thus bringing the contact portion 140 closer to a mounting surface.

When the loading surface is removed from being in contact with shielding strip 100, the resilient nature of the material out of which the shielding strip 100 and/or finger elements 124 are preferably constructed allows the finger elements 124 to return to the unloaded position. The material from which the shielding strip 100 is constructed may preferably be selected so that during use of the shielding strip 100 as a shielding and/or grounding strip, the yield point of the material is not reached and no plastic deformation of the material occurs.

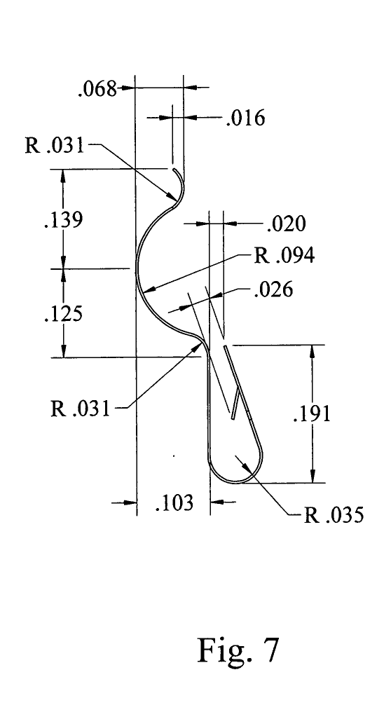

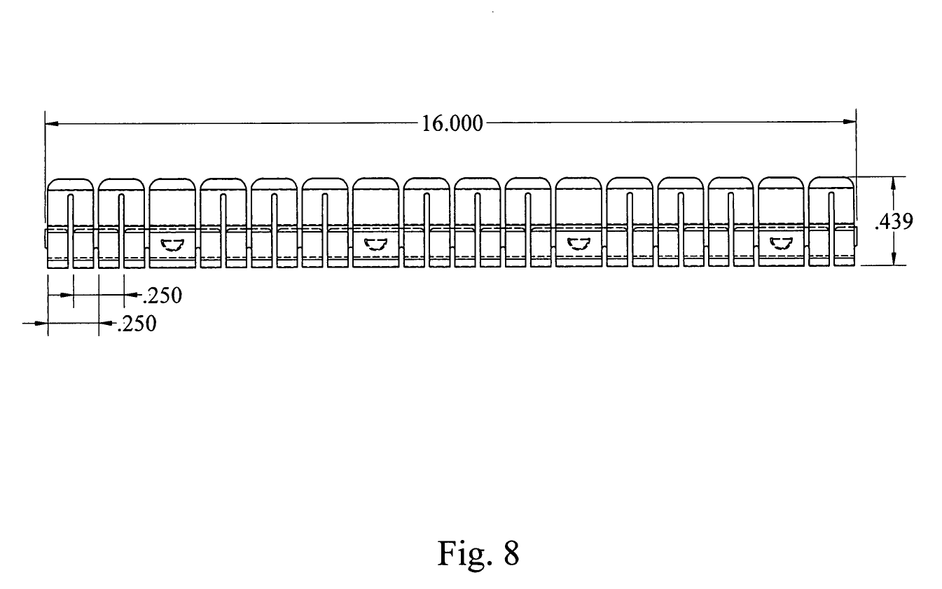

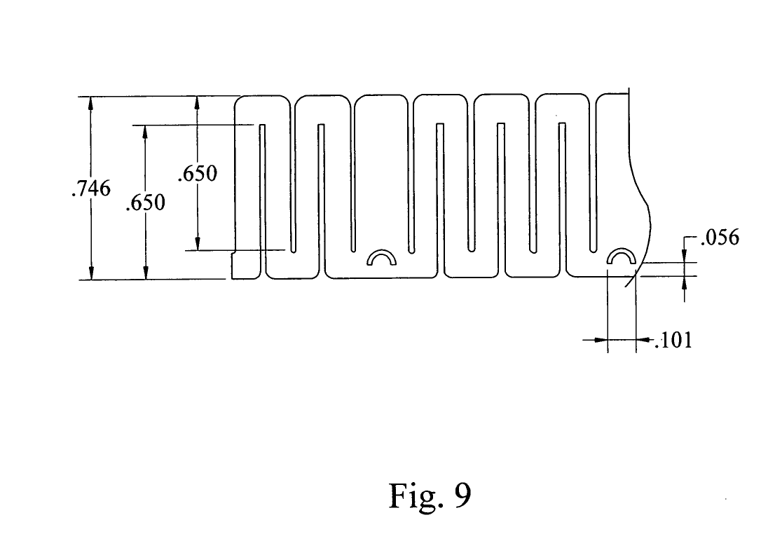

FIGS. 7 through 9 illustrate exemplary dimensions in inches that may be used for the shielding strip 100 shown in FIGS. 1 through 5 for purposes of illustration only and not for purposes of limitation. In the particular embodiment illustrated in FIGS. 7 through 9, the shielding strip 100 may have the dimensions shown therein but with a tolerance of ±0.010 inch and angular tolerances of ±3 degrees. These dimensions (as are all dimensions set forth herein) are for purposes of illustration only as the specific dimensions for a particular application can depend, for example, upon the length of the shielding strip, desired shielding effectiveness, material properties of the shielding strip, and particular installation (e.g., thickness of the mounting surface, rail, edge, etc. on which the shielding strip will be positioned, amount of curvature or bending needed for installing the shielding strip, etc.). In addition, the dimensions may vary as a function of location such that the shielding strip is thicker in one region than another to accommodate gaps of different thickness in the enclosure and connector locations. Accordingly, the dimensions of the shielding strip may be varied accordingly in order to achieve the desired contact.

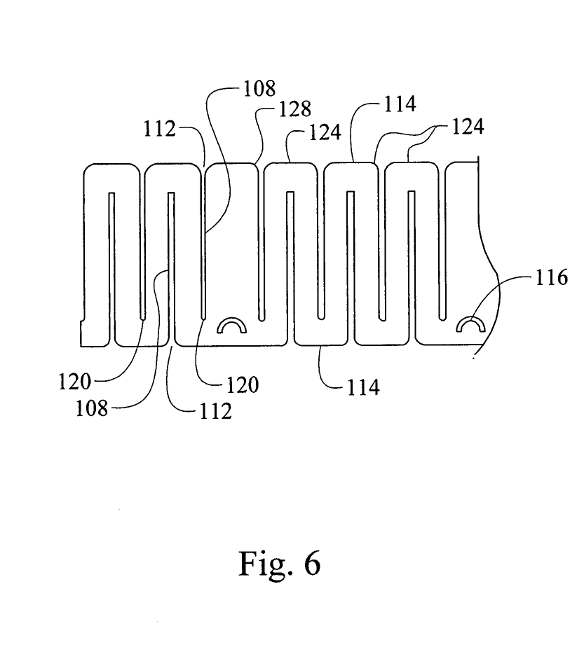

In various embodiments, the shielding strip 100 may be integrally or monolithically formed as a single component. For example, FIG. 6 illustrates a piece of material having a flat pattern that can be used for making the shielding strip 100. As shown in the figures, the shielding strip 100 includes a plurality of slots or slits 108 that define finger elements 124 therebetween. The shielding strip 100 also includes the generally D-shaped lances 116. Accordingly, this particular embodiment of the shielding strip 100 can be formed by stamping the slots or slits 108 and D-shaped lances 116 into a piece of material. After stamping this flat pattern (FIG. 6) in the piece of material, the material may be folded, bent, or otherwise formed to impart the curvatures and create the curved portions (e.g., contact portion 140, curved end portion 144, etc.) of the shielding strip 100 as shown in FIG. 4. Even though the shielding strip 100 may be formed integrally in this example, such is not required for all embodiments. For example, other embodiments may include the D-shaped lances as discrete components that are separately attached to the shielding strip 100, for example, by welding, adhesives, among other suitable methods. Alternative configurations (e.g., shapes, sizes, etc.), materials, and manufacturing methods (e.g., drawing, etc.) may be used for making the shielding strip 100.

A wide range of materials, preferably resiliently flexible and electrically conductive, may be used for a shielding strip (e.g., 100, etc.) disclosed herein. In various embodiments, the shielding strip 100 is formed from resiliently flexible material that is elastic in nature with a modulus of elasticity sufficient so that the shielding strip and/or the finger elements can be displaced by a force from an unloaded position to a loaded position, and then return to the unloaded position upon the removal of this force without exceeding the yield point of the material. Additionally, or alternatively, the shielding strip in some embodiments is formed from an electrically-conductive material capable of conducting electricity therethrough with impedance sufficiently low enough to be an effective EMI/RFI shield.

By way of further example, some embodiments include a shielding strip formed from stainless steel or beryllium copper alloy (e.g., 0.003 inches thick beryllium copper alloy 25¼ hard, etc.). The beryllium copper alloy may include between about 1.8% (weight) and about 2.0% (weight) beryllium, a maximum of about 0.6% (weight) of the combination of cobalt, nickel, and iron, and the balance copper, which alloy has an electrical conductivity of between about 22% and about 28% IACS (International Annealed Copper Standard). An example of a suitable alloy is available from Brush Wellman, Cleveland, Ohio, as Brush Alloy 25 (copper alloy UNS number C17200). Other suitable materials can also be used such as phosphor bronze, copper-clad steel, brass, monel, aluminum, steel, nickel silver, other beryllium copper alloys, among others. Furthermore, the material may optionally be pre-plated or post-plated for galvanic compatibility with the surface on which it is intended to be mounted. Alternatively, the material may be a molded or cast polymer that is loaded or coated to be electrically-conductive.

In one particular embodiment, the shielding strip 100 is formed from beryllium copper alloy 25¼ hard having an initial thickness of 0.003 inches, and which has undergone heat treating such that the diamond-pyramid hardness number (DPH) is about 373 or more using a 500 gram load. The beryllium copper alloy may be cleaned, and have a minimum thickness of about 0.0026 inches before plating.

Certain terminology is used herein for purposes of reference only, and thus is not intended to be limiting. For example, terms such as “upper”, “lower”, “above”, and “below” refer to directions in the drawings to which reference is made. Terms such as “front”, “back”, “rear”, “bottom” and “side”, describe the orientation of portions of the component within a consistent but arbitrary frame of reference which is made clear by reference to the text and the associated drawings describing the component under discussion. Such terminology may include the words specifically mentioned above, derivatives thereof, and words of similar import. Similarly, the terms “first”, “second” and other such numerical terms referring to structures do not imply a sequence or order unless clearly indicated by the context.

When introducing elements or features and the exemplary embodiments, the articles “a”, “an”, “the” and “said” are intended to mean that there are one or more of such elements or features. The terms “comprising”, “including” and “having” are intended to be inclusive and mean that there may be additional elements or features other than those specifically noted. It is further to be understood that the method steps, processes, and operations described herein are not to be construed as necessarily requiring their performance in the particular order discussed or illustrated, unless specifically identified as an order of performance. It is also to be understood that additional or alternative steps may be employed.

The description of the disclosure is merely exemplary in nature and, thus, variations that do not depart from the gist of the disclosure are intended to be within the scope of the disclosure. Such variations are not to be regarded as a departure from the spirit and scope of the disclosure.

What is claimed is:

1. A flexible clip-on shielding strip comprising:
a generally longitudinally extending region;
an array of generally transversely extending slots along the generally longitudinally extending region, each said slot having a closed end portion and an open end portion such that the closed end portions are at alternating ends of the slots and such that the open end portions are at alternating ends of the slots;
finger elements defined by the slots such that, except for every fourth finger element, each said other remaining finger element is defined generally between a corresponding pair of slots with another slot extending generally along the finger element between the corresponding pair of slots, wherein every fourth finger, instead of another slot extending generally along the fourth finger element between the corresponding pair of slots defining the fourth finger element, has a D-shaped lance feature configured for helping the shielding strip remain clipped onto a mounting surface when the D-shaped lance feature is engagingly received within an opening defined by the mounting surface.

2. The strip of claim 1, wherein the slots define the finger elements such that the shielding strip is capable of being clipped onto a curved edge portion of a mounting surface with the shielding strip serpentining about the curved edge portion.

3. The shielding strip of claim 1, wherein the shielding strip is configured to be clipped onto a curved edge portion of a mounting surface such that the shielding strip serpentines along the curved edge portion.

4. The shielding strip of claim 1, wherein the shielding strip is configured to be clipped onto an edge portion along a corner of a mounting surface such that the shielding strip wraps generally around the corner.

5. The shielding strip of claim 1, wherein a portion of the shielding strip is curved along a length of the shielding strip so as to define an arcuate contact portion.

6. The shielding strip of claim 1, wherein the generally longitudinally extending region has a generally arcuate transverse profile.

7. The shielding strip of claim 1, further comprising at least one generally transversely extending slot that has both end portions closed.

8. A flexible clip-on shielding strip configured to be clipped onto and disposed along a curved edge portion of a mounting surface, the shielding strip comprising:
an array of generally transversely extending slots, at least some of said slots having a closed end portion and an open end portion such that the closed end portions are at alternating ends of the slots and such that the open end portions are at alternating ends of the slots;
finger elements defined by the slots such that at least one of said finger elements is defined generally between a first pair of slots with at least one slot between the first pair of slots, and such that at least one other finger element is defined generally between a second pair of slots without another slot between the second pair of slots.

9. The shielding strip of claim 8, wherein the shielding strip is configured to be clipped onto a curved edge portion of a mounting surface such that the shielding strip serpentines along the curved edge portion.

10. The shielding strip of claim 8, wherein the shielding strip is configured to be clipped onto an edge portion along a corner of a mounting surface such that the shielding strip wraps generally around the corner.

11. The shielding strip of claim 8, wherein the shielding strip includes a plurality of finger elements defined between a corresponding pair of slots with at least one slot therebetween, and a plurality of finger elements defined generally between a corresponding pair of slots without another slot therebetween.

12. The shielding strip of claim 8, wherein every fourth finger element is defined by a corresponding pair of slots without another slot between the corresponding pair of slots.

13. The shielding strip of claim 8, further comprises means for helping the shielding strip remain clipped onto a mounting surface.

14. The shielding strip of claim 8, wherein the at least one other finger element further comprises at least one D-shaped lance feature configured for helping the shielding strip remain clipped onto a mounting surface when the D-shaped lance feature is engagingly received within an opening defined by the mounting surface.

15. The shielding strip of claim 8, wherein the slots define the finger elements such that the finger elements are configured for flexing relatively independently from one another.

16. The shielding strip of claim 8, wherein a portion of the shielding strip is curved along a length of the shielding strip so as to define an arcuate contact portion.

17. The shielding strip of claim 8, further comprising at least one generally transversely extending slot that has both end portions closed.

18. The shielding strip of claim 8, wherein the slots alternatingly extend from a lateral edge of the shielding strip towards the opposite lateral edge of the shielding strip.

19. The shielding strip of claim 8, wherein each said slot has a closed end portion and an open end portion such that the closed end portions are at alternating ends of the slots and such that the open end portions are at alternating ends of the slots.

20. The shielding strip of claim 8, wherein each said slot has a substantially uniform cross section.

21. A method of using a flexible clip-on shielding strip having finger elements defined by the slots such that at least one of said finger elements is defined generally between a first pair of slots with at least one slot between the first pair of slots, and such that at least one other finger element is defined generally between a second pair of slots without another slot between the second pair of slots, the method comprising clipping the shielding strip onto a curved edge portion of a mounting surface such that the shielding strip serpentines about the curved edge portion.

22. The method of claim 21, wherein the shielding strip is clipped onto the curved edge portion at a corner of the mounting surface such that the shielding strip wraps generally around the corner.

23. The method of claim 21, further comprising engagingly receiving at least one protruding portion of the shielding strip within at least one opening defined by the mounting surface to thereby help the shielding strip remain clipped onto the curved edge portion.

24. The method of claim 21, further comprising engagingly receiving at least one lance of the shielding strip within at least one opening defined by the mounting surface to thereby help the shielding strip remain clipped onto the curved edge portion.

25. The method of claim 21, wherein the at least one other finger element further comprises at least one D-shaped lance feature, and wherein the method further includes engagingly receiving the at least one D-shaped lance feature within at least one opening defined by the mounting surface to thereby help the shielding strip remain clipped onto the curved edge portion.
